(19) United States
(12) Patent Application Publication
(10) Pub. No.: US 2025/0252237 A1
(43) Pub. Date: Aug. 7, 2025

(54) Wellbore Fluid Placement Forecasting Using Dynamic Mode Decomposition

(71) Applicant: Halliburton Energy Services, Inc., Houston, TX (US)

(72) Inventors: Anoop Sheshrao Jogdand, Pune (IN); Nachiket Hemant Gokhale, Pune (IN); K V V N Krishna babu Yerubandi, Houston, TX (US); Venkata Gopala Rao Palla, Houston, TX (US); Walmy Cuello Jimenez, Houston, TX (US)

(73) Assignee: Halliburton Energy Services, Inc., Houston, TX (US)

(21) Appl. No.: 18/431,070

(22) Filed: Feb. 2, 2024

(51) Int. Cl. G06F 30/28

(52) U.S. Cl. CPC G06F 30/28

(57) ABSTRACT

A method may include: providing a cement job design comprising a pump schedule and wellbore data, wherein the pump schedule comprises a pumping rate and a volume for a plurality of wellbore fluids; identifying intrinsic dynamics of the cement job design by first forming a modified cement job design by modifying the cement job design such that the pumping rate for each of the plurality of wellbore fluids is equal and then inputting the modified cement job design into a computational fluid dynamics simulator, and generating intrinsic dynamics matrices corresponding to wellbore fluid concentration; identifying input effects of the cement job design by first forming one or more additional modified cement job design by modifying the cement job design by varying at least one of a pumping rate or a volume of the plurality of wellbore fluids and then inputting the one or more additional modified cement job design into the computational fluid dynamics simulator, and generating intrinsic dynamics matrices corresponding to wellbore fluid concentration; performing dynamic mode decomposition on the intrinsic dynamics matrices to estimate eigen values of the intrinsic dynamics matrices and performing dynamic mode decomposition on the input effects matrices to estimate eigen vectors of the input effects matrices; calculating a concentration of a fluid in an annulus using at least the pump schedule, the eigen values of the intrinsic dynamics matrices, and the eigen vectors of the input effects matrices; and performing a wellbore cementing operating according to the cement job design if the concentration of the fluid meets the cement job design.

### BACKGROUND

In subterranean well construction, a pipe string (e.g., casing, liners, expandable tubulars, etc.) may be run into a wellbore and cemented in place. The process of cementing the pipe string in place is commonly referred to as “primary cementing.” In a typical primary cementing method, cement may be pumped into an annulus between the walls of the wellbore and the exterior surface of the pipe string disposed therein. The cement composition may set in the annular space, thereby forming an annular sheath of hardened, substantially impermeable cement (i.e., a cement sheath) that may support and position the pipe string in the wellbore and may bond the exterior surface of the pipe string to the subterranean formation. Among other things, the cement sheath surrounding the pipe string prevents the migration of fluids in the annulus and protects the pipe string from corrosion. Cement may also be pumped into wellbore during, for example, remedial cementing methods to seal cracks or holes in pipe strings or cement sheaths, to seal highly permeable formation zones or fractures, or to place a cement plug and the like.

During the design phase of a cementing operation, it is often difficult to predict how cement and other fluids will behave spatially within the wellbore. Traditionally, three-dimensional computer modelling techniques have been used to predict displacement of cement with respect to the other fluids, however, these techniques are typically computationally expensive to perform, especially for wellbores having complex geometrics.

### BRIEF DESCRIPTION OF THE DRAWINGS

These drawings illustrate certain aspects of some of the embodiments of the present disclosure and should not be used to limit or define the disclosure.

FIG. 1 illustrates a schematic of timeline comparing computational run-time of a three-dimensional displacement model and a method which uses dynamic mode decomposition in accordance with one or more examples.

FIG. 2 is an illustrative depiction of a fluid displacement efficiency profile for a 3-fluid train in accordance with one or more examples.

FIG. 3 illustrates a schematic of a workflow for predicting displacement of fluids in a borehole for a cement job using dynamic mode decomposition, in accordance with one or more examples.

FIG. 4 illustrates an example of using a dynamic mode decomposition to model a cementing job, in accordance with one or more examples.

FIG. 5 is a graph showing the results of a modelled cementing job using dynamic mode decomposition, in accordance with one or more examples.

FIG. 6 illustrates an example of using a dynamic mode decomposition to model a cementing job, in accordance with one or more examples.

FIG. 7 is a graph showing the results of a modelled cementing job using dynamic mode decomposition, in accordance with one or more examples.

FIG. 8 is an illustration of an eigen pair for an operating point of open hole excess and % stand off. in accordance with one or more examples.

FIG. 9 illustrates an information handling system, in accordance with one or more examples.

FIG. 10 is an illustration of surface equipment that may be used in placement of a cement composition, in accordance with one or more examples.

FIG. 11 is an illustration of introducing a cement composition into a subterranean formation, in accordance with one or more examples.

### DETAILED DESCRIPTION

Disclosed herein are systems and methods for designing cementing operations. Particularly disclosed herein are systems and methods for computer-modelling the fluid dynamics of wellbore fluids. More particularly, disclosed herein are methods and systems which use a data-driven surrogate model using dynamic mode decomposition methods to predict transient fluid positions in a wellbore in a fast and accurate manner. Dynamic mode decomposition (DMD) identifies the most dominant features in a solution to the transient fluid positions and represents the most dominant features in a spatial mode and a temporal mode. The DMD method includes defining parameters of a wellbore cementing process and calculating spatio-temporal modes in a sampled design space for the defined parameters. Once the spatio-temporal modes are calculated, which uses DMD modal decomposition the spatio-temporal modes are used to predict a solution to transient fluid positions within a wellbore for parameters which are outside the scope previously defined parameters.

In transient fluid flow problems, such as when predicting displacement of fluids in wellbores during cementing, it is often time-consuming for a computer to solve for velocities and pressures of fluid in wellbores when fluid profile and boundary conditions are given. For example, fluid flow may be determined using projection algorithms which provide solutions for incompressible Navier-Stokes equations, which may be implemented using numerical methods (e.g., finite volume or finite difference schemes). However, because these types of methods often require discretization of space and time domains into smaller elements and volumes, the process of finding a solution becomes time-consuming. For example, some methods may require solving prime velocities, solving corrected pressures based on prime velocities, and correcting calculated velocities based on corrected pressures.

The data-driven surrogate model derived from DMD has several advantages including fast and accurate prediction of fluid displacement efficiency as compared to numerical methods such as computational fluid dynamic methods. Computational fluid dynamic methods can be run using refined grids which give better accuracy and lower grid-induced numerical diffusion; however, such approaches are computationally expensive and thus coarser grids are typically used speed computation at the expense of accuracy. Another benefit of the disclosed DMD methods is that there is retention of the full 3D nature of displacement physics. To speed computation, some fluid models make certain assumptions such as assuming 2D flow or narrow gap conditions which the present methods do not need to achieve satisfactory computational time. Another advantage of the presently disclosed methods is that the real-time prediction and forecasting of displacement can be modeled such that when there is a change in a planned operational parameter, e.g. fluid volume and/or fluid rate, the resultant fluid displacement can be quickly. Dynamic mode decomposition methods may have a performance increase of 10×-100× or more over wellbore computational fluid dynamics models which do not utilize dynamic mode decomposition. The presently disclosed methods also allow for querying for fluid distribution at any time interval during the simulation period.

Dynamic mode decomposition identifies coherent structures present in high dimensional data obtained from experiments and/or simulations. DMD provides a modal decomposition where each mode consists of spatially correlated structures that have the same linear behavior in time such as oscillations at a given frequency with growth or decay. Thus the DMD method provides a reduction in dimensionality from a reduced set of modes and how said modes evolve over time. The information captured in the spatio-temporal modes can be used at a later time for reproduction and forecasting of a physical phenomenon of interest.

The dynamic mode decomposition method take place over two phases where the first phase is the offline phase where the DMD model is built for a particular cementing job. The second phase is the online phase where the cementing job is being prepared and pumped into a borehole, and the DMD model is utilized to quickly simulate the displacement of wellbore fluids based on a user input.

The offline phase contains three principal steps. The first step is providing a cement job design and defining parameters of the wellbore cementing process and the numerical ranges thereof. The second step is to generate and store data where training data such as 3D displacement simulations at the operating conditions in a design of experiment (DOE) matrix. The third step is to perform dynamic mode decomposition on the data and build a library of reduced order models identified by a specific set of eigen pairs.

The online phase contains three principal steps. The first step is to acquire input such as at least one of a real time pump schedule of fluid types, fluid rates, and fluid volumes which are then used to predict real time fluid positions. The second step is to use the input from the first step to calculate a suitable eigen pair, such as via interpolation, from the library of eigen pairs generated in the offline phase. The third step is to use the interpolated eigen pair to predict the fluid positions in the wellbore.

Thus, implementation of dynamic mode decomposition described herein may reduce the computation cost and run-time of systems that predict displacement and/or other fluid parameters of the wellbore fluids. Such parameters may involve, to use non-limiting examples, velocity, concentration, pressure, and/or other time-varying and/or spatially varying outputs of the fluid dynamics in wellbores. In addition, this reduction in run-time may, in some examples, also allow simulations to be performed on cloud computing platforms and may allow simulations to be performed in real-time, in some examples. This may allow engineers to run more predictions, and visualize, in real-time, the output simulations, ultimately enabling them to make better decisions when creating a cement job design for a cementing operation.

“Real-time” as used herein refers to a system, apparatus, or method in which a set of input data is processed and available for use within 100 milliseconds (“ms”). In further examples, the input data may be processed and available for use within 90 ms, within 80 ms, within 70 ms, within 60 ms, within 50 ms, within 40 ms, within 30 ms, within 20 ms, or any ranges therebetween. In some examples, real-time may relate to a human's sense of time rather than a machine's sense of time. For example, processing which results in a virtually immediate output, as perceived by a human, may be considered real-time processing.

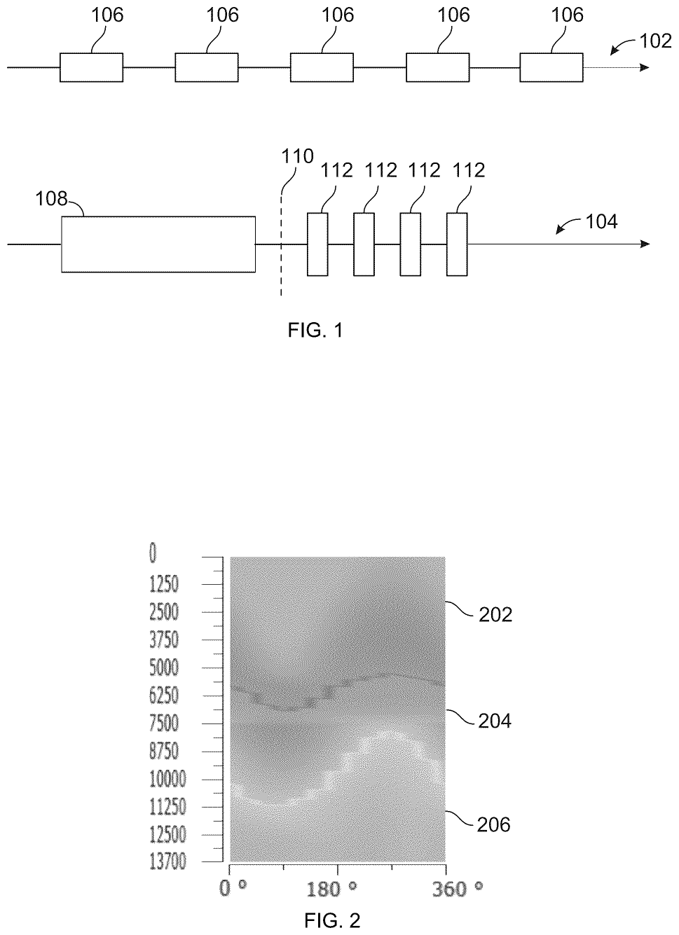

FIG. 1 illustrates a schematic of timelines 102, 104 comparing computational run-time of a three-dimensional displacement model and a method which uses DMD modal decomposition. The schematic illustration of this figure is not to scale necessarily but is intended only to show generally how the teachings and principles as applied here in may significantly improve the run-time of a computation. Timeline 102 shows the run-time of a three-dimensional model which does not use DMD modal decomposition. As illustrated, the different stages 106 of timeline 102 span a substantial length of the timeline. Timeline 102 represents how with a numerical solution approach such as a computational fluid dynamics simulation where each stage 106 takes a significant amount of time. Timeline 104 shows the run-time of a method which uses DMD modal decomposition. As illustrated, offline stage 108 takes a significant portion of time. The online portion 110 shows that each stage 112 after takes significantly less time.

As mentioned above, the methods and systems of the present disclosure are exemplary and are not intended to limit the scope of the present invention. Thus, the specific workflows described by this disclosure may be adapted to suit a particular application, such as by rearranging, omitting, or adding intervening operations and/or blocks between the various actions performed by the workflows.

One method which a cement design is evaluated is through a fluid displacement efficiency profile which maps the placement of each fluid in a fluid train in the wellbore. FIG. 2 is an illustrative depiction of a fluid displacement efficiency profile for a 3-fluid train, where the y-axis reports the measured depth of a borehole and the x axis reports the axial location from 0° to 360°. As shown in FIG. 2, first fluid 202, second fluid 204, and third fluid 206 are placed in a borehole such that first fluid 202 is displaced closest to the top of the wellbore section analyzed and third fluid 206 is placed closes to the bottom of the wellbore section analyzed. As shown in FIG. 1, the second fluid 204 was not as efficiently displaced by the third fluid 206 between measured depth 7500 and measured depth 11250 between 0° and 270°. The DMD method disclosed herein allows for a cementing engineer to quickly simulate numerous cement job designs with varying design parameters to output a fluid displacement efficiency profile for each of the cement job designs. Thus, the cementing engineer can more readily identify the parameters which will lead to an improved displacement efficiency profile and improved barrier placement. For example, if it is observed that an uneven standoff between the borehole and casing is causing channeling on one side of the casing, a cement engineer may choose to increase the density of the displacing fluid and simulating if the denser fluid provides more displacement to reduce the channeling effect.

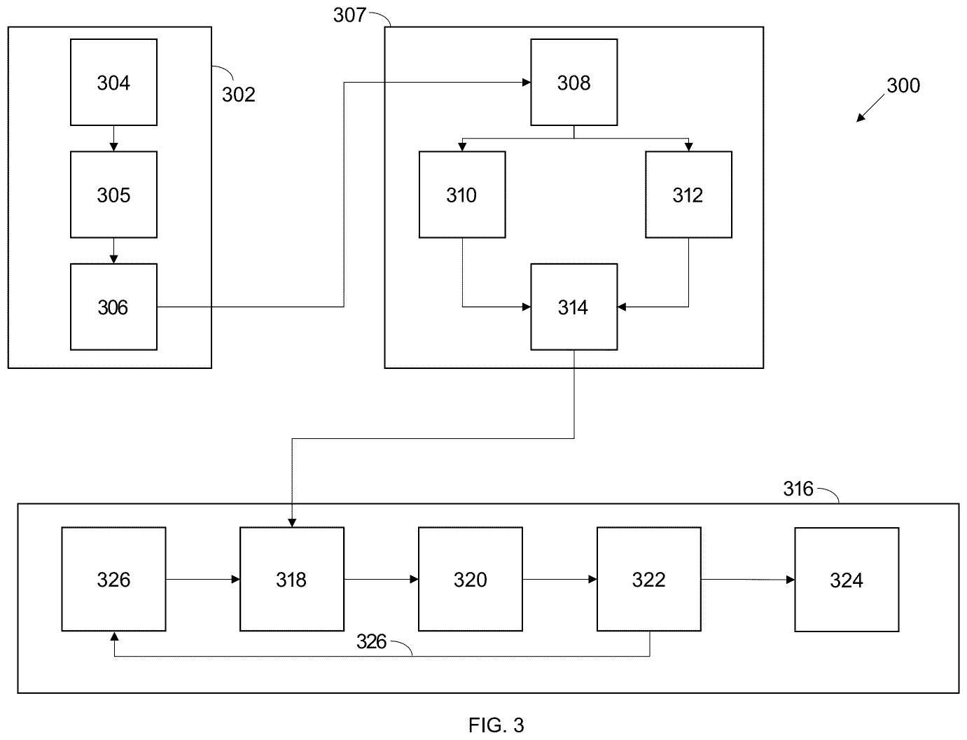

FIG. 3 illustrates a schematic of a workflow 300 for predicting displacement of fluids in a borehole for a cement job, in accordance with one or more examples. Workflow 300 begins with data generation block 302 where cementing data is generated. In block 304, a cement job design is provided. A cement job design may include one or more design parameters of a cementing operation which may include composition of wellbore fluids (e.g. drilling fluid, cement, flush, spacers, scouring fluids, fresh water, tail cement, or any other fluids for introduction into the wellbore), pumping schedule including pumping rates of each fluid and volume of each fluid, anticipated duration of the cementing operation, type of job (e.g., primary cementing, balanced plug job, squeeze cementing etc.), type of fluid circulation (e.g., forward, reverse), choice of wellbore casing (e.g. type, size, etc.), type of centralizers and planned placement of the centralizers, spacing of the various wellbore equipment (e.g., centralizers), casing movement (e.g., reciprocation, rotation, etc.), to use non-limiting examples. The cement job design may further include wellbore data may additionally, or alternatively, comprise information about a wellbore's geometry and/or geometry of one or more casings disposed therein. In embodiments, the wellbore data includes data gathered from logging including wireline logging and measurement while drilling. In other embodiments, the wellbore data include data gathered from a distributed acoustic sensing fiber optic line. The cement job design may further include an inner radius array, an outer radius array, wellbore length, wellbore diameter as a function of depth, combinations thereof, or the like, fluid properties of fluids disposed in the wellbore (e.g., density, rheology, viscosity, etc.) of a drilling fluid, for example. The cement job data may be in any suitable form such as vectors, arrays, matrices, or data representing a particular fluid relative to a spatial orientation, for example, as viscosity on a three-dimensional grid and/or density on a three-dimensional grid. The cement job design may further include a gravity array, and/or one or more fixed parameters (e.g., grid size) and defining casing movement.

The cement job design provides a basis for later predictions, as actual implementing the design parameters materially affects how the wellbore fluids will be displaced, time-dependent fluid concentration, or other fluid properties arising out of interactions between the wellbore and wellbore fluid during a cementing job. A cement job design may also comprise a target displacement of a cement and/or one or more wellbore fluids such as lead cement location, tail cement location, and spacer fluid location, for example. Other design parameters may be similarly used, such as target velocity, target concentration, combinations thereof, or the like.

At block 305 the cement job design is input into a computational model such as a commercially available computational fluid dynamics (CFD) software module, which is then used to calculate the fluid behavior in the well bore and generate data about the distribution of wellbore fluids in the wellbore annulus with time. The CFD simulation accounts for various factors such as fluid properties, flow rates, well geometry, and boundary conditions to accurately model the fluid behavior. The CFD simulation can predict the flow patterns, pressure distribution, and fluid movement in the well bore, to determine displacement. Block 306 is output from the CFD simulation which may include static and dynamic data representing the movement and position of fluid in the wellbore as well as areas of high turbulence, flow separation, or regions with low flow velocities. The output from the CFD simulation is typically in the form of arrays or matrices and the data stored therein includes various variables such as velocity components (u, v, w), concentration, pressure, temperature, and turbulence parameters. For scalar variables like pressure or temperature, the output data is typically represented as a 2D or 3D matrix, where each element of the matrix corresponds to a specific point in the computational domain. The matrix can be visualized as a grid, where each grid point contains the scalar value of the variable at that location. For vector variables such as velocity, the output data can be represented as a set of three matrices, each corresponding to the x, y, and z components of the velocity vector. These matrices represent the velocity components at each grid point in the computational domain.

A first step in block 305 is to identify the intrinsic dynamics of the wellbore system of interest. To identify the intrinsic dynamics, the pump schedule defined in data generation block 302 is modified to set the pumping rate of all fluids to be equal, and thereafter, the transient CFD simulation in run on the modified pump schedule. The output from the CFD simulation is data representing the fluid concentration distribution in the annulus stored at fixed time step intervals. Matrix 1 and Matrix 2 are illustrative matrices containing fluid concentrations of ‘k’ number of fluids defined in data generation block 302, each time interval, flattened and stacked together. In Matrix 1 and Matrix 2, the super script for ‘c’ represents time step at which the concentration data is saved the simulation from 0 to n steps, while the subscript represents the fluid index with k fluids being pumped. In Matrix 1, matrix C0, is collection of time steps from 0 to n−1 while in Matrix 2, C1 is a collection of time steps from 1 to n. The matrices contain concentration data one stime step apart, so that the dynamic mode decomposition method can decode the dynamics of the fluid concentration evolution.

$${C}_{0} = [ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ] \qquad Matrix 1$$

$${C}_{1} = [ \begin{matrix}{c}_{1}^{1} & {c}_{1}^{2} & … & {c}_{1}^{n} \\ {c}_{2}^{1} & {c}_{2}^{2} & … & {c}_{2}^{n} \\ … & … & & … \\ {c}_{k}^{1} & {c}_{k}^{2} & & {c}_{k}^{n}\end{matrix} ] \qquad Matrix 2$$

A second step in block 305 is to identify the input effect of including effect of flow rate and fluid volumes on the concentration distribution of fluids in the wellbore annulus. To identify the input effects, a transient CFD simulation is performed on the pump schedule defined in data generation block 302. The output from the CFD simulation is data representing the fluid concentration distribution in the annulus stored at fixed time step intervals. The pump schedule is modified by varying flow rates and/or volumes for one or more fluids in the pump schedule and additional CFD simulations are performed for each of the modified pump schedules. In embodiments, flow rates and volumes may be modified based on anticipated modifications during pumping of the actual cement job. For example, it may be anticipated that the actual pumping rate may be slower or faster than planned, and thus the modified pump schedules may include pump schedules with several slower rates and/or several faster rates than the pumps schedule defined in data generation block 302. Additionally, it may be anticipated that the actual pumped volumes of fluids may be greater or smaller than planned, and thus the modified pump schedules may include pump schedules with several smaller volumes of fluids and/or several larger volumes of fluids than the pumps schedule defined in data generation block 302. In an embodiment, it may be anticipated that a greater volume of spacer fluid is pumped, and the modified pump schedules may further include pump schedules with several larger rates and/or volumes of spacer fluid or any other fluid in the pump schedule. Matrix 3 and Matrix 4 are illustrative matrices containing fluid concentrations of ‘k’ number of fluids defined in data generation block 302, each time interval, flattened and stacked together. Matrix 5 is containing inlet fluid concentrations of ‘k’ number of fluids defined in data generation block 302 above, at each time interval, flattened and stacked together. Each of the matrices is output to block 306. In Matrix 3 and Matrix 4, N is total number of CFD grid cells in the domain. Each column of the C2 and C3 matrix, is constructed by arranging concentration of fluids at N locations, for k fluids, on top of each other. Hence the number of rows is N*k and each column for one time step (0-n). The matrices contain concentration data one stime step apart, so that the dynamic mode decomposition method can decode the input effects of the fluid concentration evolution. In Matrix 5, C_in is the inlet concentrations, to the wellbore, varying with time, to account for different fluids pumped. The matrix Γ₀ (Gamma0) carries information about the different fluids pumped in the domain, with time, needed for dynamic mode decomposition.

$${C}_{2} = {[ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ]}_{k \cdot N , n - 1} \qquad Matrix 3$$

$${C}_{3} = {[ \begin{matrix}{c}_{1}^{1} & {c}_{1}^{2} & … & {c}_{1}^{n} \\ {c}_{2}^{1} & {c}_{2}^{2} & … & {c}_{2}^{n} \\ … & … & & … \\ {c}_{k}^{1} & {c}_{k}^{2} & & {c}_{k}^{n}\end{matrix} ]}_{( k \cdot N , n - 1 )} \qquad Matrix 4$$

$${Γ}_{0} = {[ \begin{matrix}{c}_{1 i n}^{1} & {c}_{1 i n}^{2} & … & {c}_{1 i n}^{n - 1} \\ {c}_{2 i n}^{1} & {c}_{2 i n}^{2} & … & {c}_{2 i n}^{n - 1} \\ … & … & & … \\ {c}_{kin}^{1} & {c}_{kin}^{2} & & {c}_{kin}^{n - 1}\end{matrix} ]}_{( k , n - 1 )} \qquad Matrix 5$$

Method 100 proceeds to data processing block 307. In data processing block 307, the matrices output to block 306 are used as an input to dynamic mode decomposition block 308. Dynamic mode decomposition block 308 processes the matrices through physics informed dynamic mode decomposition, multi resolution dynamic mode decomposition, and/or dynamic mode decomposition with control. The dynamic mode decomposition forms spatial modes of fluid profiles 310 corresponding to identified input effect from block 305 and intrinsic dynamics of evolution of fluid profiles 312 corresponding to the identified intrinsic dynamics from block 305, which are stored in library 314.

Data processing block 307 includes steps to estimate the eigen values of matrices from block 306 which represent the dynamics of the fluid concentration fields (intrinsic dynamics of evolution of fluid profiles 312) and eigen vectors of matrices from block 306 which represent spatial modes of fluid concentration fields (spatial modes of fluid profiles 310) of the matrix operators A & P as in equation 5 and equation 15 where A is a linear operator matrix, that maps the concentration matrices C_0 to C_1 and P is a linear operator matrix, that maps the concentration matrices C_2 to C_3. These matrix operators are identified from the data generated in data generation block 302 and carry within them the information of the fluid concentration evolution in the wellbore annulus with time. Alternatively, the matrix operators A & P are nonlinear maps where A propagates the concentration matrices C_1 to C_0 and P propoxates concentration matrices C_2 to C_3. The Eigen pairs (Ψ_{A}, Λ_{A}, Ψ_{P}, Λ_{P}) of these operators are stored in library 314 for later use during real time processing. A step in dynamic mode decomposition includes evaluating the intrinsic component using Equation 6, which is an outcome of matrix algebra of Equations 1-5 on the generated data matrices from block 306, i.e. matrix C0 and matrix C1. A further step in dynamic mode decomposition includes evaluating the control driven component using Equation 16, which is outcome of matrix algebra of Equations 7-15, on the generated data matrices from block 306, i.e matrix C2, matrix C3, and matrix Γ₀ (Gamma0). The concentration of wellbore fluids in the annulus at any given time is calculated by summing up the intrinsic component and the control driven component as shown by Equation 17.

$${C}_{0} = U \sum {V}^{*} \qquad Equation 1$$

$$A = {U}_{r} \tilde{A} {U}_{r}^{*} \qquad Equation 2$$

$$\tilde{A} = {U}_{r}^{*} {C}_{1} {V}_{r} {\sum }_{r}^{- 1} \qquad Equation 3$$

$$\tilde{A} = {\tilde{Ψ}}_{A} {Λ}_{A} \qquad Equation 4$$

$${Ψ}_{A} = {C}_{1} V {\sum }_{r}^{- 1} \qquad Equation 5$$

$${C}_{int , t} = {Ψ}_{A} {Λ}_{A}^{t - 1} b , b = {Ψ}_{A}^{+} {c}_{0} \qquad Equation 6$$

$${C}_{3} = P {C}_{2} + Q {Γ}_{0} \qquad Equation 7$$

$$Ω = [ \begin{matrix}{C}_{2} \\ {Γ}_{0}\end{matrix} ] \qquad Equation 8$$

$$Ω = \tilde{U} \tilde{\sum } , truncated to rank p \qquad Equation 9$$

$$\tilde{U} = \qquad Equation 10$$

$${C}_{3} = \hat{U} \hat{\sum } \qquad Equation 11$$

$$\tilde{P} = \hat{U} {C}_{3} \tilde{V} \hat{U} \qquad Equation 12$$

$$\tilde{Q} = {C}_{3} \tilde{V} \qquad Equation 13$$

$$\tilde{P} = {Λ}_{p} \qquad Equation 14$$

$${Ψ}_{p} = {C}_{3} \tilde{V} \qquad Equation 15$$

$${C}_{c , t} = {Ψ}_{P} {Λ}_{P}^{t - 1} b + Q {Γ}_{0} \qquad Equation 16$$

$${C}_{t} = {C}_{int , t} + {C}_{c , t} \qquad Equation 17$$

The symbols used in Equations 1-17 are as follows: C₀, C₁—Matrices with concentration data from simulation and with altered pump schedule, C₀=UΣV* represents singular value decomposition of matrix C₀, U is proper orthogonal decomposition modes, where Σ is a diagonal singular values matrix, V is the right singular vector, V* is complex conjugate matrix of V, A—linear operator matrix, that maps the concentration matrices C₁=AC₀, Ã—reduced matrix of rank ‘r’ to be constructed to replace the full-order matrix A, Uᵣ: reduced matrix of rank ‘r’ of U, U*ᵣ: Complex conjugate of Uᵣ, Σᵣ⁻¹: inverse of reduced ‘r’ rank matrix Σ, Ψ_{A}: Full rank eigen vectors of matrix A, [symbol] : ‘r’ rank eigen vectors of matrix A, Λ_{A}: Eigen values of matrix A, Ψ_{A}⁺: Moore Penrose Pseudo inverse of matrix Ψ_{A}, b: matrix with initial condition information, t: time step, C_{int,t}: intrinsic dynamics of the system identified from eqn 6, C₂, C₃-matrices with concentration data from simulation with actual pump schedule, P is system matrix, Q is control matrix, Γ₀ is matrix with all inlet concentrations (control input), Ω isa stacked matrix formed out of C₂ and Γ₀, Ω=Ũ\tilde{Σ} [symbol] represents singular value decomposition of matrix Ω, truncated to rank ‘p, Ũ₁ is rank ‘p’ proper orthogonal decomposition modes of C₂, Ũ₂ is rank ‘p’ proper orthogonal decomposition modes of Γ₀, Ũ is stacked matrix of Ũ₁, Ũ₂, \tilde{Σ} is a diagonal singular values matrix of Ω, [symbol] is complex conjugate of the right singular vector \tilde{V}, C₃=Ũ\tilde{Σ} [symbol] represents singular value decomposition of matrix Ω, truncated to rank ‘p’, U is proper orthogonal decomposition modes of C₃, \hat{Σ} is a diagonal singular values matrix of C₃, [symbol] is complex conjugate of the right singular vector \hat{V}, \tilde{P} is reduced matric of rank ‘p’ constructed from P, \tilde{Q} is reduced matric of rank ‘p’ constructed from Q, Vᵣ is a reduced matrix of rank ‘r’ of V, ψ_{P} is full rank eigen vectors of matrix P, [symbol] is ‘p’ rank eigen vectors of matrix P, Λₚ is eigen values of matrix P, b is a matrix with initial condition information, t is time step, and C_{c,t} is controlled dynamics of the system identified from Equation 17. System matrix P and control matrix Q are determined by equation 12 and 13 by keeping only part of the matrix to control the state-variable such as concentration.

Method 100 proceeds to online block 316 where the model developed in processing block 307 is utilized to simulate wellbore fluid displacement. Online block 316 begins by providing a pump schedule in block 326 which includes fluid volumes and pump rates for each of the fluids to be pumped into the wellbore. In block 318, the spatial modes and dynamics of evolution corresponding to the pump schedule provided in block 326 are retrieved from library 314. In embodiments, the exact values may not be present in the library so intermediate points may be interpolated as necessary. In block 320 the Eigen pairs that are retrieved from library 314 are used to estimate the concentration of the fluids in the wellbore using Equations 6, 16, and 17. In block 322 the fluid distribution in the wellbore is analysed to see if the placement of fluids, such as the top of cement to a specified depth, is satisfactory. If the placement is not satisfactory, a user can alter the pump schedule by varying rate and/or volumes of the fluids and the altered pump schedule is used as input, as shown by arrow 326, to block 326 where the altered pump schedule is provided. In block 318, the spatial modes and dynamics of evolution corresponding to the altered pump schedule provided in block 326 are retrieved from library 314 with interpolation if necessary. Once the simulated fluid placement is satisfactory, method too proceeds to block 324 where the pump schedule provided in block 326 is used. For example, the pumps may be operated such that the rates and volumes of fluid defined in the pump schedule are pumped into the borehole.

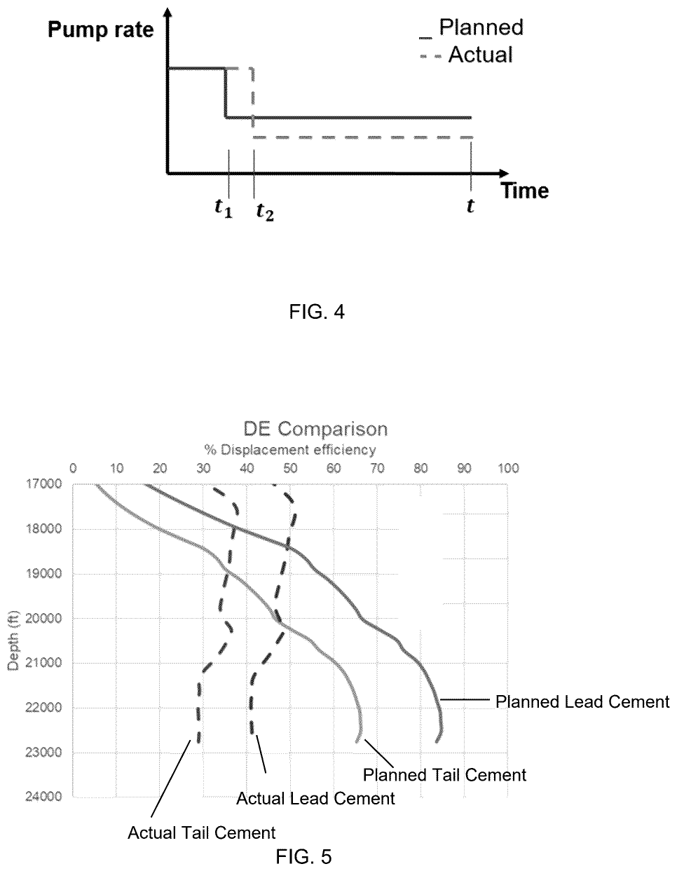

FIG. 4 illustrates an example of using a dynamic mode decomposition to model a cementing job. In FIG. 4, the solid line is the planned pumping rate. At time t1, circumstances at the rig do not permit the planned profile and the actual pump rate starting at t2 is shown by the dashed line. This is when the cementing engineer can modify the pump schedule as in block 326 in FIG. 3 to match the actual pumping rate starting at t2. The placement of fluids in the wellbore is then determined using the dynamic mode decomposition technique and the modified pump schedule. FIG. 5 is a graph showing the results of the displacement for the original planned schedule and the actually pumped schedule. It can be observed that the displacement efficiency for the modified schedule is less than the original planned schedule and corrective action can be planned.

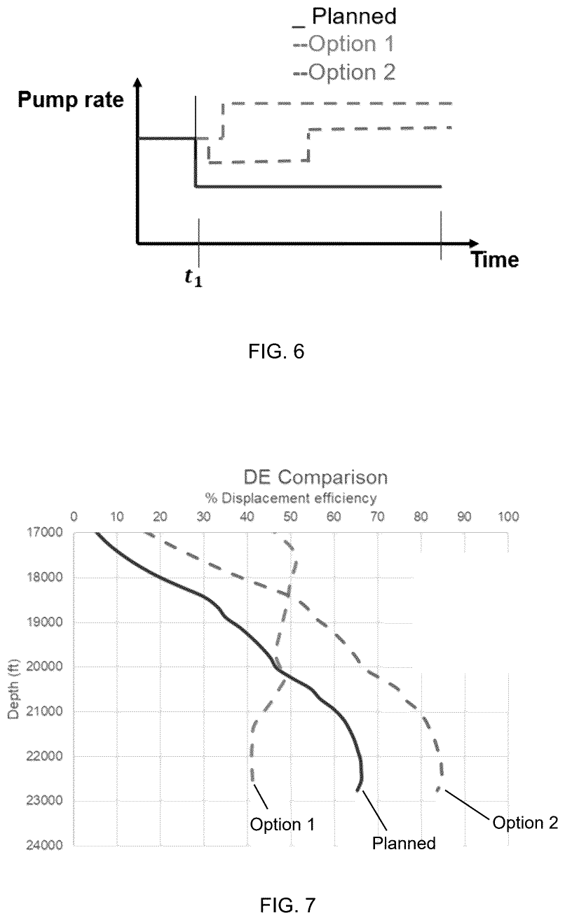

FIG. 6 illustrates another example of using a dynamic mode decomposition to model a cementing job. In FIG. 6, the solid line indicated the planned pumping rate. At time t1, it may be observed from real time monitoring that one or more job parameters is not proceeding according to plan. This may be due to assumptions made during the planning stage such as the casing centralisation, open hole size, and formation properties, for example, which are influencing the progress of the cementing job. This is when the cementing engineer can use the dynamic mode decomposition technique to simulate multiple pump scheduled to be followed for the remainder of the job and generate results of the fluid concentrations. Thus the engineer can select the best pump schedule to follow which allows for satisfactory displacement. FIG. 7 illustrates the displacement efficiency between option 1 where the rate is immediately increased after t1 and option 2 where the rate is kept lower for an initial period before the rate is increased. It can be observed that option 2 produces better displacement than option 1. The dynamic mode deposition method thus allows for multiple pump schedules to be quickly simulated to select the schedule which gives satisfactory displacement.

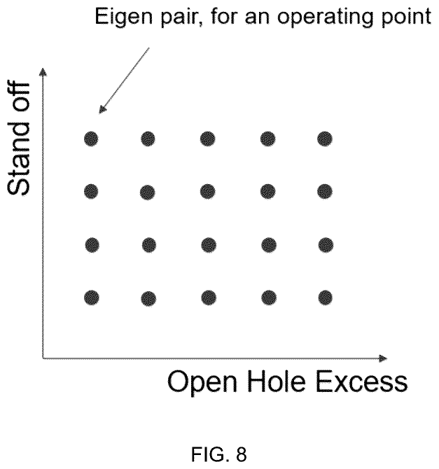

In further embodiments, the wellbore conditions such as centralisation in terms of % stand off and the open hole excess based on the actual drilling conditions can also be used as a variable in the dynamic mode decomposition technique. FIG. 8 is a illustration of an eigen pair for an operating point of open hole excess and % stand off. In these embodiments, the cement job design, such as the cement job design provided in block 304, can include variation in wellbore parameters such as % stand off 40-75 and open hole excess of 10-35%, for example, and the dynamic mode decomposition technique is repeated for each parameter combination such that such that library 314 includes eigenpairs for each combination. During the online phase the centralization conditions can be changed to any values that were simulated during the offline phase and the displacement for any centralization condition can be quickly determined by selecting the correct eigenpair.

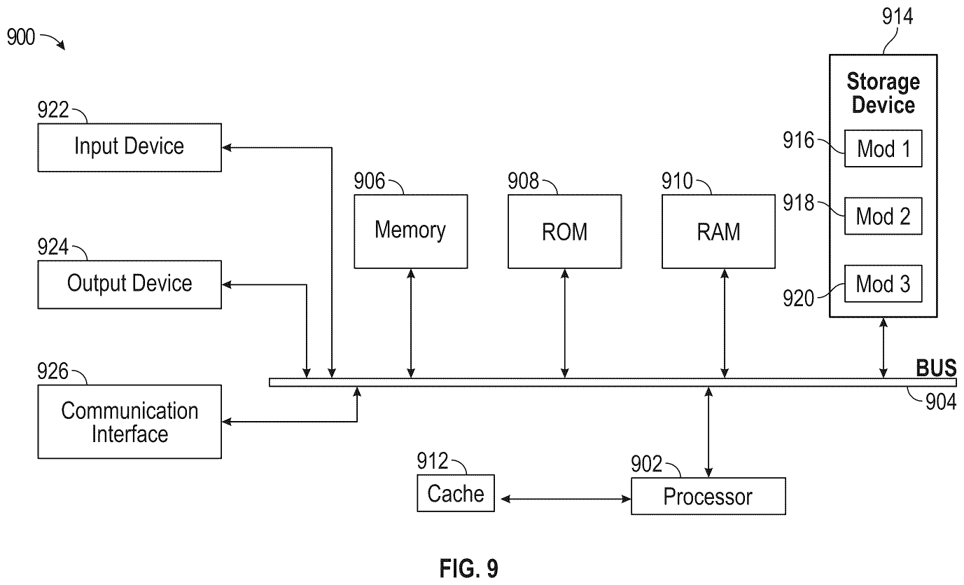

FIG. 9 illustrates an example information handling system 900 which may be employed to perform various steps, methods, and techniques disclosed herein. As illustrated, information handling system 900 includes a processing unit (CPU or processor) 902 and a system bus 904 that couples various system components including system memory 906 such as read only memory (ROM) 908 and random-access memory (RAM) 910 to processor 902. Processors disclosed herein may all be forms of this processor 902. Information handling system 900 may include a cache 912 of high-speed memory connected directly with, in close proximity to, or integrated as part of processor 902. Information handling system 900 copies data from memory 906 and/or storage device 914 to cache 912 for quick access by processor 902. In this way, cache 912 provides a performance boost that avoids processor 902 delays while waiting for data. These and other modules may control or be configured to control processor 902 to perform various operations or actions. Another system memory 906 may be available for use as well. Memory 906 may include multiple different types of memory with different performance characteristics. It may be appreciated that the disclosure may operate on information handling system 900 with more than one processor 902 or on a group or cluster of computing devices networked together to provide greater processing capability. Processor 902 may include any general-purpose processor and a hardware module or software module, such as first module 916, second module 918, and third module 920 stored in storage device 914, configured to control processor 902 as well as a special-purpose processor where software instructions are incorporated into processor 902.

Processor 902 may be a self-contained computing system, containing multiple cores or processors, a bus, memory controller, cache, etc. A multi-core processor may be symmetric or asymmetric. Processor 902 may include multiple processors, such as a system having multiple, physically separate processors in different sockets, or a system having multiple processor cores on a single physical chip. Similarly, processor 902 may include multiple distributed processors located in multiple separate computing devices but working together such as via a communications network. Multiple processors or processor cores may share resources such as memory 906 or cache 912 or may operate using independent resources. Processor 902 may include one or more state machines, an application specific integrated circuit (ASIC), or a programmable gate array (PGA) including a field PGA (FPGA).

Each individual component discussed above may be coupled to system bus 904, which may connect each and every individual component to each other. System bus 904 may be any of several types of bus structures including a memory bus or memory controller, a peripheral bus, and a local bus using any of a variety of bus architectures. A basic input/output (BIOS) stored in ROM 908 or the like, may provide the basic routine that helps to transfer information between elements within information handling system 900, such as during start-up. Information handling system 900 further includes storage devices 914 or computer-readable storage media such as a hard disk drive, a magnetic disk drive, an optical disk drive, tape drive, solid-state drive, RAM drive, removable storage devices, a redundant array of inexpensive disks (RAID), hybrid storage device, or the like. Storage device 914 may include software modules 916, 918, and 920 for controlling processor 902. Information handling system 900 may include other hardware or software modules. Storage device 914 is connected to the system bus 904 by a drive interface. The drives and the associated computer-readable storage devices provide nonvolatile storage of computer-readable instructions, data structures, program modules and other data for information handling system 900. In one aspect, a hardware module that performs a particular function includes the software component stored in a tangible computer-readable storage device in connection with the necessary hardware components, such as processor 902, system bus 904, and so forth, to carry out a particular function. In another aspect, the system may use a processor and computer-readable storage device to store instructions which, when executed by the processor, cause the processor to perform operations, a method, or other specific actions. The basic components and appropriate variations may be modified depending on the type of device, such as whether information handling system 900 is a small, handheld computing device, a desktop computer, a computer server, or a cloud infrastructure. When processor 902 executes instructions to perform “operations”, processor 902 may perform the operations directly and/or facilitate, direct, or cooperate with another device or component to perform the operations.

As illustrated, information handling system 900 employs storage device 914, which may be a hard disk or other types of computer-readable storage devices which may store data that are accessible by a computer, such as magnetic cassettes, flash memory cards, digital versatile disks (DVDs), cartridges, random access memories (RAMs) 910, read only memory (ROM) 908, a cable containing a bit stream and the like, may also be used in the exemplary operating environment. Tangible computer-readable storage media, computer-readable storage devices, or computer-readable memory devices, expressly exclude media such as transitory waves, energy, carrier signals, electromagnetic waves, and signals per se.

To enable user interaction with information handling system 900, an input device 922 represents any number of input mechanisms, such as a microphone for speech, a touch-sensitive screen for gesture or graphical input, keyboard, mouse, motion input, speech and so forth. Additionally, input device 922 may take in data from one or more downhole sensors, discussed above. An output device 924 may also be one or more of a number of output mechanisms known to those of skill in the art. In some instances, multimodal systems enable a user to provide multiple types of input to communicate with information handling system 900. Communications interface 926 generally governs and manages the user input and system output. There is no restriction on operating on any particular hardware arrangement and therefore the basic hardware depicted may easily be substituted for improved hardware or firmware arrangements as they are developed.

As illustrated, each individual component described above is depicted and disclosed as individual functional blocks. The functions these blocks represent may be provided through the use of either shared or dedicated hardware, including, but not limited to, hardware capable of executing software and hardware, such as a processor 902, that is purpose-built to operate as an equivalent to software executing on a general-purpose processor. For example, the functions of one or more processors presented in FIG. 9 may be provided by a single shared processor or multiple processors. (Use of the term “processor” should not be construed to refer exclusively to hardware capable of executing software.) Illustrative embodiments may include microprocessor and/or digital signal processor (DSP) hardware, read-only memory (ROM) 908 for storing software performing the operations described below, and random-access memory (RAM) 910 for storing results. Very large-scale integration (VLSI) hardware embodiments, as well as custom VLSI circuitry in combination with a general-purpose DSP circuit, may also be provided.

The logical operations of the various methods, described below, are implemented as: (1) a sequence of computer implemented steps, operations, or procedures running on a programmable circuit within a general use computer, (2) a sequence of computer implemented steps, operations, or procedures running on a specific-use programmable circuit; and/or (3) interconnected machine modules or program engines within the programmable circuits. Information handling system 900 may practice all or part of the recited methods, may be a part of the recited systems, and/or may operate according to instructions in the recited tangible computer-readable storage devices. Such logical operations may be implemented as modules configured to control processor 902 to perform particular functions according to the programming of software modules 916, 918, and 920.

In examples, one or more parts of the example information handling system 900, up to and including the entire information handling system 900, may be virtualized. For example, a virtual processor may be a software object that executes according to a particular instruction set, even when a physical processor of the same type as the virtual processor is unavailable. A virtualization layer or a virtual “host” may enable virtualized components of one or more different computing devices or device types by translating virtualized operations to actual operations. Ultimately however, virtualized hardware of every type is implemented or executed by some underlying physical hardware. Thus, a virtualization computer layer may operate on top of a physical computer layer. The virtualization computer layer may include one or more virtual machines, an overlay network, a hypervisor, virtual switching, and any other virtualization application.

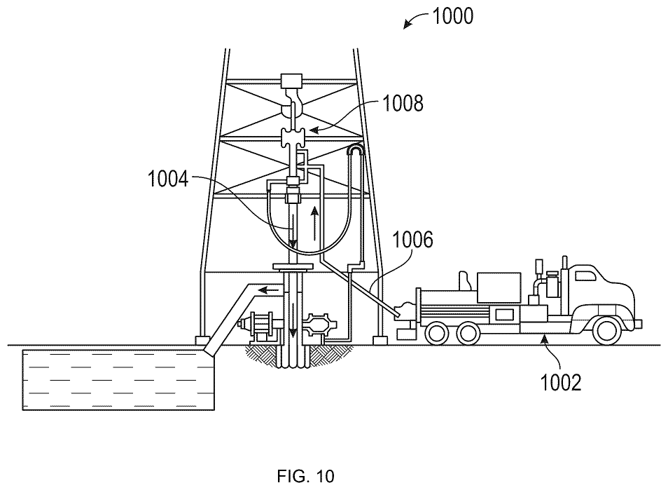

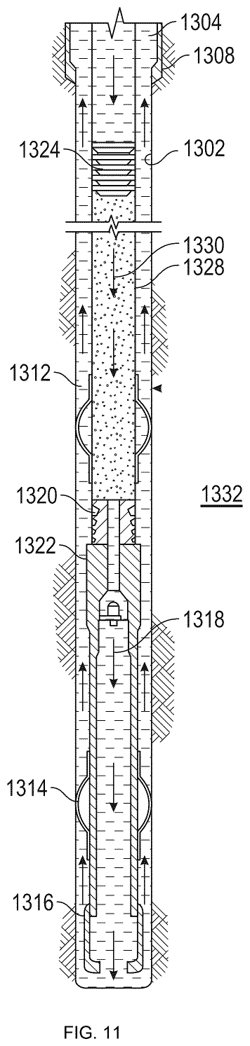

An example technique and system for placing a cement composition into a subterranean formation will now be described with reference to FIGS. 10 and 11. As mentioned previously, cement may be pumped into a wellbore after fine-tuning the design parameters of a cementing operation according to any of the workflows previously disclosed. Such design parameters may include, for example, volume, pumping rate, pumping schedule, cement composition, combinations thereof, as well as wellbore parameters including standoff and open hole excess or the like. FIG. 10 illustrates surface equipment 1000 that may be used in placement of a cement composition in accordance with certain embodiments. It should be noted that while FIG. 10 generally depicts a land-based operation, those skilled in the art will readily recognize that the principles described herein are equally applicable to subsea operations that employ floating or sea-based platforms and rigs, without departing from the scope of the disclosure. As illustrated by FIG. 10, the surface equipment 1000 may include a cementing unit 1002, which may include one or more cement trucks. The cementing unit 1002 may include mixing equipment and pumping equipment as will be apparent to those of ordinary skill in the art. The cementing unit 1002 may pump a cement composition 1004 through a feed pipe 1006 and to a cementing head 1008 which conveys the cement composition 1004 downhole.

Turning now to FIG. 11, the cement composition 1004 may be placed into a subterranean formation 1332 in accordance with example embodiments. As illustrated, a wellbore 1302 may be drilled into the subterranean formation 1302. While wellbore 1302 is shown extending generally vertically into the subterranean formation 1302, the principles described herein are also applicable to wellbores that extend at an angle through the subterranean formation 1302, such as horizontal and slanted wellbores. In the illustrated embodiments, a surface casing 1304 has been inserted into the wellbore 1302. The surface casing 1304 may be cemented to the walls 1306 of the wellbore 1302 by cement sheath 1308. In the illustrated embodiment, one or more additional conduits (e.g., intermediate casing, production casing, liners, etc.) shown here as casing 1328 may also be disposed in the wellbore 1302. As illustrated, there is a wellbore annulus 1312 formed between the casing 1328 and the walls 1306 of the wellbore 1302 and/or the surface casing 1304. One or more centralizers 1314 may be attached to the casing 1328, for example, to centralize the casing 1328 in the wellbore 1302 prior to and during the cementing operation.

With continued reference to FIG. 13, the cement composition 1330 may be pumped down the interior of the casing 1304. The cement composition 1330 may be allowed to flow down the interior of the casing 1304 through the casing shoe 1316 at the bottom of the casing 1304 and up around the casing 1328 into the wellbore annulus 1312. The cement composition 1330 may be allowed to set in the wellbore annulus 1312, for example, to form a cement sheath that supports and positions the casing 1328 in the wellbore 1302. While not illustrated, other techniques may also be utilized for introduction of the cement composition 1330. By way of example, reverse circulation techniques may be used that include introducing the cement composition 1330 into the subterranean formation 1302 by way of the wellbore annulus 1312 instead of through the casing 1328.

As it is introduced, the cement composition 1330 may displace other fluids 1318, such as drilling fluids and/or spacer fluids, that may be present in the interior of the casing 1328 and/or the wellbore annulus 1312. At least a portion of the displaced fluids 1318 may exit the wellbore annulus 1312 via a flow line and be deposited, for example, in one or more retention pits (e.g., a mud pit), as shown on FIG. 12. Referring again to FIG. 13, a bottom plug 1320 may be introduced into the wellbore 1302 ahead of the cement composition 1330, for example, to separate the cement composition 1330 from the fluids 1318 that may be inside the casing 1328 prior to cementing. In other examples, fluids 1318 and cement composition 1330 may be in fluidic communication. After the bottom plug 1320 reaches the landing collar 1322, a diaphragm or other suitable device may rupture, in some examples, to allow the cement composition 1330 through bottom plug 1320. In FIG. 13, the bottom plug 1320 is shown on the landing collar 1322. In the illustrated embodiment, a top plug 1324 may be introduced into the wellbore 1302 behind the cement composition 1330. The top plug 1324 may separate the cement composition 1330 from a displacement fluid 50 and also push the cement composition 1330 through the bottom plug 1320.

Specific improvements associated with some embodiments of the present disclosure may include, in some examples, an improved ability to design a cementing operation, improved accuracy of predictions while still maintaining low run-time, reduction in the need for time and expertise for designing the cementing operations, reduction in the number of redundancies and/or iterations in a workflow to converge to a solution, and a reduction or elimination in the number of intermediate solutions required to achieve an output. In some examples, improvements may comprise an ability to simulate three-dimensional displacement problems more quickly, which may allow engineers to perform more simulations and make better decisions about their designs. In some examples, improvements may enable real-time three-dimensional calculations. For example, this may enable engineers to visualize results of a simulation during rendering, thereby allowing them to better understand a problem and make more informed decisions. In some examples, other improvements may include an ability to perform sensitivity analysis and/or automated optimization. This may involve, for example, automating one or more operations of the workflows disclosed herein. Also, real-time availability of the predicted output using the one or more dynamic mode decomposition techniques as disclosed herein may reduce the total amount of pumping time required to perform a cementing operation by accelerating the pumping schedule.

The disclosed cement may also directly or indirectly affect the various downhole equipment and tools that can come into contact with wellbore treatment fluids during operations. Such equipment and tools may include, without limitation, wellbore casing, wellbore liner, completion string, insert strings, drill string, coiled tubing, slickline, wireline, drill pipe, drill collars, mud motors, downhole motors and/or pumps, surface-mounted motors and/or pumps, centralizers, turbolizers, scratchers, floats (e.g., shoes, collars, valves, and the like), logging tools and related telemetry equipment, actuators (e.g., electromechanical devices, hydromechanical devices, and the like), sliding sleeves, production sleeves, plugs, screens, filters, flow control devices (e.g., inflow control devices, autonomous inflow control devices, outflow control devices, and the like), coupling (e.g., electro-hydraulic wet connect, dry connect, inductive coupler, and the like), control lines (e.g., electrical, fiber optic, hydraulic, and the like), surveillance lines, drill bits and reamers, sensors or distributed sensors, downhole heat exchangers, valves and corresponding actuation devices, tool seals, packers, cement plugs, bridge plugs, and other wellbore isolation devices or components, and the like. Any of these components can be included in the systems and apparatuses generally described in the foregoing.

Accordingly, the present disclosure may provide methods and systems for using pre-trained physics informed neural networks for designing cementing jobs in wellbore operations. The method and systems may include any of the various features disclosed herein, including one or more of the following statements.

Statement 1: A method comprising: providing intrinsic dynamics matrices and input effects matrices corresponding to a cement job design wherein the cement job design comprises a pump schedule and wellbore data and wherein the pump schedule comprises a pumping rate and a volume for a plurality of wellbore fluids; performing dynamic mode decomposition on the intrinsic dynamics matrices to estimate eigen values of the intrinsic dynamics matrices and performing dynamic mode decomposition on the input effects matrices to estimate eigen vectors of the input effects matrices; calculating a concentration of a fluid in an annulus using at least the pump schedule, the eigen values of the intrinsic dynamics matrices, and the eigen vectors of the input effects matrices; and performing a wellbore cementing operating according to the cement job design if the concentration of the fluid meets the cement job design.

Statement 2. The method of statement 1 further comprising identifying intrinsic dynamics of the cement job design by first forming a modified cement job design by modifying the cement job design such that the pumping rate for each of the plurality of wellbore fluids is equal and then inputting the modified cement job design into a computational fluid dynamics simulator, and generating intrinsic dynamics matrices corresponding to wellbore fluid concentration.

Statement 3. The method of any of statements 1-2 further comprising identifying input effects of the cement job design by first forming one or more additional modified cement job design by modifying the cement job design by varying at least one of a pumping rate or a volume of the plurality of wellbore fluids and then inputting the one or more additional modified cement job design into the computational fluid dynamics simulator, and generating intrinsic dynamics matrices corresponding to wellbore fluid concentration.

Statement 4. The method of any of statements 1-3 wherein the intrinsic dynamics matrices have the form of Matrix 1 and/or Matrix 2,

$${C}_{0} = [ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ] \qquad Matrix 1$$

$${C}_{1} = [ \begin{matrix}{c}_{1}^{1} & {c}_{1}^{2} & … & {c}_{1}^{n} \\ {c}_{2}^{1} & {c}_{2}^{2} & … & {c}_{2}^{n} \\ … & … & & … \\ {c}_{k}^{1} & {c}_{k}^{2} & & {c}_{k}^{n}\end{matrix} ] \qquad Matrix 2$$

where C represents fluid concentration at a from 0 to n steps, and k is a fluid index.

Statement 5. The method of any of statements 1-4 wherein the input effects matrices have the form of Matrix 3, Matrix 4, and/or Matrix 5,

$${C}_{2} = {[ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ]}_{k \cdot N , n - 1} \qquad Matrix 3$$

$${C}_{3} = {[ \begin{matrix}{c}_{1}^{1} & {c}_{1}^{2} & … & {c}_{1}^{n} \\ {c}_{2}^{1} & {c}_{2}^{2} & … & {c}_{2}^{n} \\ … & … & & … \\ {c}_{k}^{1} & {c}_{k}^{2} & & {c}_{k}^{n}\end{matrix} ]}_{( k \cdot N , n - 1 )} \qquad Matrix 4$$

$${Γ}_{0} = {[ \begin{matrix}{c}_{1 in}^{1} & {c}_{1 in}^{2} & … & {c}_{1 in}^{n - 1} \\ {c}_{2 in}^{1} & {c}_{2 in}^{2} & … & {c}_{2 in}^{n - 1} \\ … & … & & … \\ {c}_{kin}^{1} & {c}_{kin}^{2} & & {c}_{kin}^{n - 1}\end{matrix} ]}_{( k , n - 1 )} \qquad Matrix 5$$

where C represents fluid concentration at a from 0 to n steps, k is a fluid index, and N is total number of CFD grid cells in the domain.

Statement 6. The method of any of statements 1-5 wherein estimating eigen values comprise utilizing an equation of the form of Equation 6, C_{int,t}=Ψ_{A}Λ_{A}^{t-1}b, b=Ψ_{A}⁺c₀ where C_{int,t} is intrinsic dynamics, Ψ_{A} is full rank eigen vectors of matrix A, Λ_{A}^{t-1} is the (t−1)^{th} power of Ψ_{A}, b is matrix with initial condition information, b is a projection of c₀ which is Matrix 1, and Ψ_{A}⁺ is Moore Penrose Pseudo inverse of matrix Ψ_{A}.

Statement 7. The method of statement 6 wherein estimating eigen values further comprise utilizing an equation of the form of Equations 1-5 Equation 1 C₀=UΣV* Equation 2 A=UᵣÃU*ᵣ Equation 3 Ã=U*ᵣC₁VᵣΣᵣ⁻¹ Equation 4 Ã [symbol] =\tilde{Ψ}_{A}Λ_{A} Equation 5 Ψ_{A}=C₁VΣᵣ⁻¹ [symbol] where C0 is Matrix 1, U is Proper Orthogonal decomposition modes, Σ is a diagonal singular values matrix, V is a right singular vector, and V*is a complex conjugate matrix of V, A is a linear operator matrix that maps Matrix 2 to C₁=AC₀, Uᵣ is reduced matrix of rank ‘r’ of U, Ã is a reduced matrix of rank ‘r’ constructed to replace full-order matrix A, U*ᵣ is a complex conjugate of Uᵣ, Vᵣ is a reduced matrix of rank ‘r’ of V, Σᵣ⁻¹ is the inverse of reduced ‘r’ rank matrix Σ, [symbol] is ‘r’ rank eigen vectors of matrix A, Λ_{A} is eigen values of matrix A, and Ψ_{A} is full rank eigen vectors of matrix A.

Statement 8. The method of any of statements 1-7 wherein estimating eigen vectors comprise utilizing an equation of the form of Equation 16, C_{c,t}=Ψ_{P}Λ_{P}^{t-1}b+Quᵢ where C_{c,t} is controlled dynamics, where Ψ_{P} is full rank eigen vectors of system matrix P, Λ_{P}^{t-1} is the (t−1)^{th} power of Ψ_{P}, b is a matrix with initial condition information, Q is a control matrix, and uᵢ is a control.

Statement 9. The method of statement 7 wherein estimating eigen vectors further comprise utilizing an equation of the form of Equations 7-15

$${C}_{3} = {PC}_{2} + Q {Γ}_{0} = {[ \begin{matrix}{c}_{1}^{1} & {c}_{1}^{2} & … & {c}_{1}^{n} \\ {c}_{2}^{1} & {c}_{2}^{2} & … & {c}_{2}^{n} \\ … & … & & … \\ {c}_{k}^{1} & {c}_{k}^{2} & & {c}_{k}^{n}\end{matrix} ]}_{( k \cdot N , n - 1 )} \qquad Equation 7$$

$$Ω = [ \begin{matrix}{C}_{2} \\ {Γ}_{0}\end{matrix} ] = [ \begin{matrix}{[ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ]}_{k \cdot N , n - 1} \\ {[ \begin{matrix}{c}_{1 in}^{1} & {c}_{1 in}^{2} & … & {c}_{1 in}^{n - 1} \\ {c}_{2 in}^{1} & {c}_{2 in}^{2} & … & {c}_{2 in}^{n - 1} \\ … & … & & … \\ {c}_{kin}^{1} & {c}_{kin}^{2} & & {c}_{kin}^{n - 1}\end{matrix} ]}_{( k , n - 1 )}\end{matrix} ] \qquad Equation 8$$

$$Ω = \tilde{U} \tilde{Σ} , \qquad Equation 9$$

truncated to rank p Equation 10

$$\tilde{U} =$$

Equation 11 C₃=Û\hat{Σ} [symbol] Equation 12 \tilde{P}=ÛC₃ [symbol] Equation 13 \tilde{Q}= [symbol] Equation 14 \tilde{P} [symbol] 32 [symbol] Λₚ Equation 15 Ψₚ= [symbol] where C represents fluid concentration at a from 0 to n steps, k is a fluid index, and N is total number of CFD grid cells in the domain, Ũ is a stacked matrix of Ũ₁ and Ũ₂, where Ũ₁ is rank ‘p’ proper orthogonal decomposition modes of C₂, Ũ₂ is rank ‘p’ proper orthogonal decomposition modes of Γ₀, \tilde{Σ} is a diagonal singular values matrix of Ω, [symbol] is a complex conjugate of right singular vector Û₁, \tilde{Q} is a reduced matrix of rank ‘p’ constructed from system matrix P, Û is proper orthogonal decomposition modes of C₃, [symbol] is inverse of \tilde{E}, [symbol] is a complex conjugate of Û₁, \tilde{Q} is a reduced matrix of rank ‘p’ constructed from Q, Û* is a complex conjugate of Û, [symbol] is a complex conjugate of Û₂, [symbol] is ‘p’ rank eigen vectors of matrix P, Λₚ is eigen values of matrix P, and Ψ_{P} is full rank eigen vectors of matrix P.

Statement 10. The method of statement 7 wherein calculating a location of a fluid in an annulus comprises utilizing an equation of the form of equation 17Cₜ=C_{int,t}+C_{c,t}.

Statement 11. A method comprising: providing a cement job design comprising a pump schedule and wellbore data, wherein the pump schedule comprises a pumping rate and a volume for a plurality of wellbore fluids, eigen values corresponding to intrinsic dynamics matrices derived from the cement job design, and eigen vectors of corresponding to input effects matrices derived from the cement job design; generating a time-varying predicted displacement using at least the cement job design, the eigen values of the intrinsic dynamics matrices, and the eigen vectors of the input effects matrices; comparing the time-varying predicted displacement with a target displacement; updating the cement job design to form an updated cement job design by adjusting at least one of the pumping rate or the volume for one or more of the plurality of wellbore fluids, and repeating the step of generating until the time-varying predicted displacement converges to the target displacement; and performing a cementing operation based at least in part on the updated cement job design.

Statement 12. The method of statement 11 wherein updating the cement job design further comprises updating at least one input selected from the group consisting of a fluid property, viscosity on a three-dimensional grid, density on a three-dimensional grid, fluid concentration on a three-dimensional grid, density of a cement to be pumped into the wellbore, a wellbore geometry, an array of inner radii of a casing and/or borehole for a plurality of depths of the wellbore, an array of outer radii of a casing and/or borehole for the plurality of depths of the wellbore, an array of wellbore standoff for the plurality of depths of the wellbore, a gravity vector, grid size, and any combination thereof.

Statement 13. The method of any of statements 11-12 wherein generating a time-varying predicted displacement comprises utilizing an equation of the form of Cₜ=C_{int,t}+C_{c,t}.

Statement 14. The method of any of statements 11-13 wherein the target displacement comprises at least one of lead cement location, tail cement location, or spacer fluid location.

Statement 15. The method of any of statements 11-14 further comprising based on the time-varying predicted displacement, modifying a pump schedule of at least one wellbore treatment fluid selected from the group consisting of a spacer fluid, a cement, a flush fluid, a pad fluid, an acid, a clean-up fluid, a wettability modifying fluid, a surfactant-based fluid, and any combination thereof.

Statement 16. The method of any of statements 11-15 further comprising displaying the time-varying prediction on a display device if the time-varying prediction reaches a steady state.

Statement 17. The method of any of statements 11-16 further comprising identifying intrinsic dynamics of the cement job design by first forming a modified cement job design by modifying the cement job design such that the pumping rate for each of the plurality of wellbore fluids is equal and then inputting the modified cement job design into a computational fluid dynamics simulator, and generating matrices corresponding to the intrinsic dynamics, wherein the intrinsic dynamics matrices comprise velocity components (u, v, w), pressure, temperature, and turbulence parameters.

Statement 18. The method of statement 17 further comprising identifying input effects of the cement job design by first forming one or more additional modified cement job design by modifying the cement job design by varying at least one of a pumping rate or a volume of the plurality of wellbore fluids and then inputting the one or more additional modified cement job design into the computational fluid dynamics simulator, and generating matrices corresponding to the input effects, wherein the input effects matrices comprise velocity components (u, v, w), pressure, temperature, and turbulence parameters.

Statement 19. The method of statement 18 further comprising performing dynamic mode decomposition on the intrinsic dynamics matrices to estimate eigen values of the intrinsic dynamics matrices and performing dynamic mode decomposition on the input effects matrices to estimate eigen vectors of the input effects matrices.

Statement 20. The method of statement 19 wherein estimating eigen values comprise utilizing an equation of the form of Equation 6, Equation 6 C_{int,t}=Ψ_{A}Λ_{A}^{t-1}b, b=Ψ_{A}⁺c₀ where C_{int,t} is intrinsic dynamics, Ψ_{A} is full rank eigen vectors of matrix A, Λ_{A}^{t-1} is the (t−1)^{th} power of Ψ_{A}, b is matrix with initial condition information, b is a projection of which is Matrix 1, and Ψ_{A}⁺ is Moore Penrose Pseudo inverse of matrix Ψ_{A}.

Statement 21 The method of any of statements 11-20 wherein estimating eigen vectors comprise utilizing an equation of the form of Equation 16, C_{c,t}=Ψ_{P}Λ_{P}^{t-1}b+Quᵢ where C_{c,t} is controlled dynamics, where Ψ_{P} is full rank eigen vectors of system matrix P, Λ_{P}^{t-1} is the (t−1)^{th} power of Ψ_{P}, b is a matrix with initial condition information, Q is a control matrix, and uᵢ is a control.

Statement 22. The method of any of statements 11-21 wherein estimating eigen values further comprise utilizing an equation of the form of each of Equations 1-5 and 7-15

$${C}_{0} = U Σ {V}^{*} = [ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ] \qquad Equation 1$$

$$A = {U}_{r} \tilde{A} {U}_{r}^{*} \qquad Equation 2$$

$$\tilde{A} = {U}_{r}^{*} {C}_{1} {V}_{r} {Σ}_{r}^{- 1} \qquad Equation 3$$

$$\tilde{A} = {Λ}_{A} \qquad Equation 4$$

$${Ψ}_{A} = {C}_{1} V {Σ}_{r}^{- 1} \qquad Equation 5$$

$${C}_{3} = {PC}_{2} + Q {Γ}_{0} = {[ \begin{matrix}{c}_{1}^{1} & {c}_{1}^{2} & … & {c}_{1}^{n} \\ {c}_{2}^{1} & {c}_{2}^{2} & … & {c}_{2}^{n} \\ … & … & & … \\ {c}_{k}^{1} & {c}_{k}^{2} & & {c}_{k}^{n}\end{matrix} ]}_{( k \cdot N , n - 1 )} \qquad Equation 7$$

$$Ω = [ \begin{matrix}{C}_{2} \\ {Γ}_{0}\end{matrix} ] = [ \begin{matrix}{[ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ]}_{k \cdot N , n - 1} \\ {[ \begin{matrix}{c}_{1 in}^{1} & {c}_{1 in}^{2} & … & {c}_{1 in}^{n - 1} \\ {c}_{2 in}^{1} & {c}_{2 in}^{2} & … & {c}_{2 in}^{n - 1} \\ … & … & & … \\ {c}_{kin}^{1} & {c}_{kin}^{2} & & {c}_{kin}^{n - 1}\end{matrix} ]}_{( k , n - 1 )}\end{matrix} ] \qquad Equation 8$$

$$Ω = \tilde{U} \tilde{Σ} , \qquad Equation 9$$

truncated to rank p

$$\tilde{U} = \qquad Equation 10$$

Equation 11 C₃=Û\hat{Σ} [symbol] Equation 12 \tilde{P}=ÛC₃ [symbol] Equation 13 \tilde{Q}= [symbol] Equation 14 \tilde{P} [symbol] = [symbol] Λₚ Equation 15 Ψₚ=C₃ [symbol] where C represents fluid concentration at a from 0 to n steps, k is a fluid index, and N is total number of CFD grid cells in the domain, Ũ is a stacked matrix of Ũ₁ and Ũ₂, where Ũ₁ is rank ‘p’ proper orthogonal decomposition modes of C₂, Ũ₂ is rank ‘p’ proper orthogonal decomposition modes of Γ₀, \tilde{Σ} is a diagonal singular values matrix of Ω, \tilde{V}* is a complex conjugate of right singular vector \tilde{V}, \tilde{P} is a reduced matrix of rank ‘p’ constructed from system matrix P, Û is proper orthogonal decomposition modes of C₃, [symbol] is inverse of \tilde{Σ}, [symbol] is a complex conjugate of Ũ₁, \tilde{Q} is a reduced matrix of rank ‘p’ constructed from Q, [symbol] is a complex conjugate of Û, [symbol] is a complex conjugate of Ũ₂, [symbol] is ‘p’ rank eigen vectors of matrix P, Λₚ is eigen values of matrix P, Ψ_{P} is full rank eigen vectors of matrix P, U is Proper Orthogonal decomposition modes, Σ is a diagonal singular values matrix, V is a right singular vector, and V* is a complex conjugate matrix of V, A is a linear operator matrix that maps Matrix 2 to C₁=AC₀, Uᵣ is reduced matrix of rank ‘r’ of U, Ã is a reduced matrix of rank ‘r’ constructed to replace full-order matrix A, U*ᵣ is a complex conjugate of Uᵣ, Vᵣ is a reduced matrix of rank ‘r’ of V, Σᵣ⁻¹ is the inverse of reduced ‘r’ rank matrix Σ, [symbol] is ‘r’ rank eigen vectors of matrix A, Λ_{A} is eigen values of matrix A, and Ψ_{A} is full rank eigen vectors of matrix A.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any included range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited. Although specific examples have been described above, these examples are not intended to limit the scope of the present disclosure, even where only a single example is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Various advantages of the present disclosure have been described herein, but examples may provide some, all, or none of such advantages, or may provide other advantages.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

Therefore, the present embodiments are well adapted to attain the ends and advantages mentioned as well as those that are inherent therein. The particular embodiments disclosed above are illustrative only, as the present embodiments may be modified and practiced in different but equivalent manners apparent to those skilled in the art having the benefit of the teachings herein. Although individual embodiments are discussed, all combinations of each embodiment are contemplated and covered by the disclosure. Furthermore, no limitations are intended to the details of construction or design shown herein, other than as described in the claims below. Also, the terms in the claims have their plain, ordinary meaning unless otherwise explicitly and clearly defined by the patentee. It is therefore evident that the particular illustrative embodiments disclosed above may be altered or modified and all such variations are considered within the scope and spirit of the present disclosure.

What is claimed is:

1. A method comprising:
providing intrinsic dynamics matrices and input effects matrices corresponding to a cement job design wherein the cement job design comprises a pump schedule and wellbore data and wherein the pump schedule comprises a pumping rate and a volume for a plurality of wellbore fluids;
performing dynamic mode decomposition on the intrinsic dynamics matrices to estimate eigen values of the intrinsic dynamics matrices and performing dynamic mode decomposition on the input effects matrices to estimate eigen vectors of the input effects matrices;
calculating a concentration of a fluid in an annulus using at least the pump schedule, the eigen values of the intrinsic dynamics matrices, and the eigen vectors of the input effects matrices; and
performing a wellbore cementing operating according to the cement job design if the concentration of the fluid meets the cement job design.

2. The method of claim 1 further comprising identifying intrinsic dynamics of the cement job design by first forming a modified cement job design by modifying the cement job design such that the pumping rate for each of the plurality of wellbore fluids is equal and then inputting the modified cement job design into a computational fluid dynamics simulator, and generating intrinsic dynamics matrices corresponding to wellbore fluid concentration.

3. The method of claim 1 further comprising identifying input effects of the cement job design by first forming one or more additional modified cement job design by modifying the cement job design by varying at least one of a pumping rate or a volume of the plurality of wellbore fluids and then inputting the one or more additional modified cement job design into the computational fluid dynamics simulator, and generating intrinsic dynamics matrices corresponding to wellbore fluid concentration.

4. The method of claim 1 wherein the intrinsic dynamics matrices have the form of Matrix 1 and/or Matrix 2,
$${C}_{0} = [ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ] \qquad Matrix 1$$
$${C}_{1} = [ \begin{matrix}{c}_{1}^{1} & {c}_{1}^{2} & … & {c}_{1}^{n} \\ {c}_{2}^{1} & {c}_{2}^{2} & … & {c}_{2}^{n} \\ … & … & & … \\ {c}_{k}^{1} & {c}_{k}^{2} & & {c}_{k}^{n}\end{matrix} ] \qquad Matrix 2$$
where C represents fluid concentration at a from 0 to n steps, and k is a fluid index.

5. The method of claim 1 wherein the input effects matrices have the form of Matrix 3, Matrix 4, and/or Matrix 5,
$${C}_{2} = {[ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ]}_{k \cdot N , n - 1} \qquad Matrix 3$$
$${C}_{3} = {[ \begin{matrix}{c}_{1}^{1} & {c}_{1}^{2} & … & {c}_{1}^{n} \\ {c}_{2}^{1} & {c}_{2}^{2} & … & {c}_{2}^{n} \\ … & … & & … \\ {c}_{k}^{1} & {c}_{k}^{2} & & {c}_{k}^{n}\end{matrix} ]}_{( k \cdot N , n - 1 )} \qquad Matrix 4$$
$${Γ}_{0} = {[ \begin{matrix}{c}_{1 in}^{1} & {c}_{1 in}^{2} & … & {c}_{1 in}^{n - 1} \\ {c}_{2 in}^{1} & {c}_{2 in}^{2} & … & {c}_{2 in}^{n - 1} \\ … & … & & … \\ {c}_{kin}^{1} & {c}_{kin}^{2} & & {c}_{kin}^{n - 1}\end{matrix} ]}_{( k , n - 1 )} \qquad Matrix 5$$
where C represents fluid concentration at a from 0 to n steps, k is a fluid index, and N is total number of CFD grid cells in the domain.

6. The method of claim 1 wherein estimating eigen values comprise utilizing an equation of the form of Equation 6,
$${C}_{int , t} = {Ψ}_{A} {Λ}_{A}^{t - 1} b , b = {Ψ}_{A}^{+} {c}_{0} \qquad Equation 6$$
where C_{int,t} is intrinsic dynamics, Ψ_{A} is full rank eigen vectors of matrix A, Λ_{A}^{t-1} is the (t−1)^{th} power of Ψ_{A}, b is matrix with initial condition information, b is a projection of c₀ which is Matrix 1, and Ψ_{A}⁺ is Moore Penrose Pseudo inverse of matrix Ψ_{A}.

7. The method of claim 6 wherein estimating eigen values further comprise utilizing an equation of the form of each of Equations 1-5
$${C}_{0} = U Σ {V}^{*} \qquad Equation 1$$
$$A = {U}_{r} \tilde{A} {U}_{r}^{*} \qquad Equation 2$$
$$\tilde{A} = {U}_{r}^{*} {C}_{1} {V}_{r} {Σ}_{r}^{- 1} \qquad Equation 3$$
$$\tilde{A} = {Λ}_{A} \qquad Equation 4$$
$${Ψ}_{A} = {C}_{1} V {Σ}_{r}^{- 1} \qquad Equation 5$$
where C0 is Matrix 1, U is Proper Orthogonal decomposition modes, Σ is a diagonal singular values matrix, V is a right singular vector, and V* is a complex conjugate matrix of V, A is a linear operator matrix that maps Matrix 2 to C₁=AC₀, Uᵣ is reduced matrix of rank ‘r’ of U, Ã is a reduced matrix of rank ‘r’ constructed to replace full-order matrix A, U*ᵣ is a complex conjugate of Uᵣ, Vᵣ is a reduced matrix of rank ‘r’ of V, Σᵣ⁻¹ is the inverse of reduced ‘r’ rank matrix Σ, [symbol] is ‘r’ rank eigen vectors of matrix A, Λ_{A} is eigen values of matrix A, and Ψ_{A} is full rank eigen vectors of matrix A.

8. The method of claim 1 wherein estimating eigen vectors comprise utilizing an equation of the form of Equation 16,
$${C}_{c , t} = {Ψ}_{P} {Λ}_{P}^{t - 1} b + {Qu}_{i} \qquad Equation 16$$
where C_{c,t} is controlled dynamics, where Ψ_{P} is full rank eigen vectors of system matrix P, Λ_{P}^{t-1} is the (t−1)^{th} power of Ψ_{P}, b is a matrix with initial condition information, Q is a control matrix, and uᵢ is a control.

9. The method of claim 8 wherein estimating eigen vectors further comprise utilizing an equation of the form of each of Equations 7-15
$${C}_{3} = {PC}_{2} + Q {Γ}_{0} = {[ \begin{matrix}{c}_{1}^{1} & {c}_{1}^{2} & … & {c}_{1}^{n} \\ {c}_{2}^{1} & {c}_{2}^{2} & … & {c}_{2}^{n} \\ … & … & & … \\ {c}_{k}^{1} & {c}_{k}^{2} & & {c}_{k}^{n}\end{matrix} ]}_{( k \cdot N , n - 1 )} \qquad Equation 7$$
$$Ω = [ \begin{matrix}{C}_{2} \\ {Γ}_{0}\end{matrix} ] = [ \begin{matrix}{[ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ]}_{k \cdot N , n - 1} \\ {[ \begin{matrix}{c}_{1 in}^{1} & {c}_{1 in}^{2} & … & {c}_{1 in}^{n - 1} \\ {c}_{2 in}^{1} & {c}_{2 in}^{2} & … & {c}_{2 in}^{n - 1} \\ … & … & & … \\ {c}_{kin}^{1} & {c}_{kin}^{2} & & {c}_{kin}^{n - 1}\end{matrix} ]}_{( k , n - 1 )}\end{matrix} ] \qquad Equation 8$$
$$Ω = \tilde{U} \tilde{Σ} , truncated to rank p \qquad Equation 9$$
$$\tilde{U} = \qquad Equation 10$$
$${C}_{3} = \hat{U} \hat{Σ} \qquad Equation 11$$
$$\tilde{P} = \hat{U} {C}_{3} \qquad Equation 12$$
$$\tilde{Q} = \qquad Equation 13$$
$$\tilde{P} = {Λ}_{p} \qquad Equation 14$$
$${Ψ}_{p} = {C}_{3} \tilde{V} \qquad Equation 15$$
where C represents fluid concentration at a from 0 to n steps, k is a fluid index, and N is total number of CFD grid cells in the domain, Ũ is a stacked matrix of Ũ₁ and Ũ₂, where Ũ₁ is rank ‘p’ proper orthogonal decomposition modes of C₂, Ũ₂ is rank ‘p’ proper orthogonal decomposition modes of Γ₀, \tilde{Σ} is a diagonal singular values matrix of Ω, [symbol] is a complex conjugate of right singular vector \tilde{V}, \tilde{P} is a reduced matrix of rank ‘p’ constructed from system matrix P, Û is proper orthogonal decomposition modes of C₃, [symbol] is inverse of \tilde{Σ}, [symbol] is a complex conjugate of Ũ₁, \tilde{Q} is a reduced matrix of rank ‘p’ constructed from Q, [symbol] is a complex conjugate of Û, [symbol] is a complex conjugate of Ũ₂, [symbol] is ‘p’ rank eigen vectors of matrix P, Λₚ is eigen values of matrix P, and Ψ_{P} is full rank eigen vectors of matrix P.

10. The method of claim 9 wherein calculating a location of a fluid in an annulus comprises utilizing an equation of the form of equation 17
$${C}_{t} = {C}_{int , t} + {C}_{c , t} . \qquad Equation 17$$

11. A method comprising:
providing a cement job design comprising a pump schedule and wellbore data, wherein the pump schedule comprises a pumping rate and a volume for a plurality of wellbore fluids, eigen values corresponding to intrinsic dynamics matrices derived from the cement job design, and eigen vectors of corresponding to input effects matrices derived from the cement job design;
generating a time-varying predicted displacement using at least the cement job design, the eigen values of the intrinsic dynamics matrices, and the eigen vectors of the input effects matrices;
comparing the time-varying predicted displacement with a target displacement;
updating the cement job design to form an updated cement job design by adjusting at least one of the pumping rate or the volume for one or more of the plurality of wellbore fluids, and repeating the step of generating until the time-varying predicted displacement converges to the target displacement; and
performing a cementing operation based at least in part on the updated cement job design.

12. The method of claim 11 wherein updating the cement job design further comprises updating at least one input selected from the group consisting of a fluid property, viscosity on a three-dimensional grid, density on a three-dimensional grid, fluid concentration on a three-dimensional grid, density of a cement to be pumped into the wellbore, a wellbore geometry, an array of inner radii of a casing and/or borehole for a plurality of depths of the wellbore, an array of outer radii of a casing and/or borehole for the plurality of depths of the wellbore, an array of wellbore standoff for the plurality of depths of the wellbore, a gravity vector, grid size, and any combination thereof.

13. The method of claim 11 wherein generating a time-varying predicted displacement comprises utilizing an equation of the form of Cₜ=C_{int,t}+C_{c,t}.

14. The method of claim 11 wherein the target displacement comprises at least one of lead cement location, tail cement location, or spacer fluid location.

15. The method of claim 11 further comprising based on the time-varying predicted displacement, modifying a pump schedule of at least one wellbore treatment fluid selected from the group consisting of a spacer fluid, a cement, a flush fluid, a pad fluid, an acid, a clean-up fluid, a wettability modifying fluid, a surfactant-based fluid, and any combination thereof.

16. The method of claim 11 further comprising displaying the time-varying prediction on a display device if the time-varying prediction reaches a steady state.

17. The method of claim 11 further comprising identifying intrinsic dynamics of the cement job design by first forming a modified cement job design by modifying the cement job design such that the pumping rate for each of the plurality of wellbore fluids is equal and then inputting the modified cement job design into a computational fluid dynamics simulator, and generating matrices corresponding to the intrinsic dynamics, wherein the intrinsic dynamics matrices comprise velocity components (u, v, w), pressure, temperature, and turbulence parameters.

18. The method of claim 17 further comprising identifying input effects of the cement job design by first forming one or more additional modified cement job design by modifying the cement job design by varying at least one of a pumping rate or a volume of the plurality of wellbore fluids and then inputting the one or more additional modified cement job design into the computational fluid dynamics simulator, and generating matrices corresponding to the input effects, wherein the input effects matrices comprise velocity components (u, v, w), pressure, temperature, and turbulence parameters.

19. The method of claim 18 further comprising performing dynamic mode decomposition on the intrinsic dynamics matrices to estimate eigen values of the intrinsic dynamics matrices and performing dynamic mode decomposition on the input effects matrices to estimate eigen vectors of the input effects matrices.

20. The method of claim 19 wherein estimating eigen values comprise utilizing an equation of the form of Equation 6,
$${C}_{int , t} = {Ψ}_{A} {Λ}_{A}^{t - 1} b , b = {Ψ}_{A}^{+} {c}_{0} \qquad Equation 6$$
where C_{int,t} is intrinsic dynamics, Ψ_{A} is full rank eigen vectors of matrix A, Λ_{A}^{t-1} is the (t−1)^{th} power of Ψ_{A}, b is matrix with initial condition information, b is a projection of which is Matrix 1, and Ψ_{A}⁺ is Moore Penrose Pseudo inverse of matrix Ψ_{A}.

21. The method of claim 19 wherein estimating eigen vectors comprise utilizing an equation of the form of Equation 16,
$${C}_{c , t} = {Ψ}_{P} {Λ}_{P}^{t - 1} b + {Qu}_{i} \qquad Equation 16$$
where C_{c,t} is controlled dynamics, where Ψ_{P} is full rank eigen vectors of system matrix P, Λ_{P}^{t-1} is the (t−1)^{th} power of Ψ_{P}, b is a matrix with initial condition information, Q is a control matrix, and uᵢ is a control.

22. The method of claim 19 wherein estimating eigen values further comprise utilizing an equation of the form of each of Equations 1-5 and 7-15
$${C}_{0} = U Σ {V}^{*} = [ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ] \qquad Equation 1$$
$$A = {U}_{r} \tilde{A} {U}_{r}^{*} \qquad Equation 2$$
$$\tilde{A} = {U}_{r}^{*} {C}_{1} {V}_{r} {Σ}_{r}^{- 1} \qquad Equation 3$$
$$\tilde{A} = {Λ}_{A} \qquad Equation 4$$
$${Ψ}_{A} = {C}_{1} V {Σ}_{r}^{- 1} \qquad Equation 5$$
$${C}_{3} = {PC}_{2} + Q {Γ}_{0} = {[ \begin{matrix}{c}_{1}^{1} & {c}_{1}^{2} & … & {c}_{1}^{n} \\ {c}_{2}^{1} & {c}_{2}^{2} & … & {c}_{2}^{n} \\ … & … & & … \\ {c}_{k}^{1} & {c}_{k}^{2} & & {c}_{k}^{n}\end{matrix} ]}_{( k \cdot N , n - 1 )} \qquad Equation 7$$
$$Ω = [ \begin{matrix}{C}_{2} \\ {Γ}_{0}\end{matrix} ] = [ \begin{matrix}{[ \begin{matrix}{c}_{1}^{0} & {c}_{1}^{1} & … & {c}_{1}^{n - 1} \\ {c}_{2}^{0} & {c}_{2}^{1} & … & {c}_{2}^{n - 1} \\ … & … & & … \\ {c}_{k}^{0} & {c}_{k}^{1} & & {c}_{k}^{n - 1}\end{matrix} ]}_{k \cdot N , n - 1} \\ {[ \begin{matrix}{c}_{1 in}^{1} & {c}_{1 in}^{2} & … & {c}_{1 in}^{n - 1} \\ {c}_{2 in}^{1} & {c}_{2 in}^{2} & … & {c}_{2 in}^{n - 1} \\ … & … & & … \\ {c}_{kin}^{1} & {c}_{kin}^{2} & & {c}_{kin}^{n - 1}\end{matrix} ]}_{( k , n - 1 )}\end{matrix} ] \qquad Equation 8$$
$$Ω = \tilde{U} \tilde{Σ} , truncated to rank p \qquad Equation 9$$
$$\tilde{U} = \qquad Equation 10$$
$${C}_{3} = \hat{U} \hat{Σ} \qquad Equation 11$$
$$\tilde{P} = \hat{U} {C}_{3} \qquad Equation 12$$
$$\tilde{Q} = \qquad Equation 13$$
$$\tilde{P} = {Λ}_{p} \qquad Equation 14$$
$${Ψ}_{p} = {C}_{3} \qquad Equation 15$$
where C represents fluid concentration at a from 0 to n steps, k is a fluid index, and N is total number of CFD grid cells in the domain, Ũ is a stacked matrix of Ũ₁ and Ũ₂, where Ũ₁ is rank ‘p’ proper orthogonal decomposition modes of C₂, Ũ₂ is rank ‘p’ proper orthogonal decomposition modes of Γ₀, \tilde{Σ} is a diagonal singular values matrix of Ω, [symbol] is a complex conjugate of right singular vector \tilde{V}, \tilde{P} is a reduced matrix of rank ‘p’ constructed from system matrix P, Û is proper orthogonal decomposition modes of C₃, [symbol] is inverse of \tilde{Σ}, [symbol] is a complex conjugate of Ũ₁, \tilde{Q} is a reduced matrix of rank ‘p’ constructed from Q, [symbol] is a complex conjugate of Û, [symbol] is a complex conjugate of Ũ₂, [symbol] is ‘p’ rank eigen vectors of matrix P, Λₚ is eigen values of matrix P, Ψ_{P} is full rank eigen vectors of matrix P, U is Proper Orthogonal decomposition modes, Σ is a diagonal singular values matrix, V is a right singular vector, and V* is a complex conjugate matrix of V, A is a linear operator matrix that maps Matrix 2 to C₁=AC₀, Uᵣ is reduced matrix of rank ‘r’ of U, Ã is a reduced matrix of rank ‘r’ constructed to replace full-order matrix A, U*ᵣ is a complex conjugate of Uᵣ, Vᵣ is a reduced matrix of rank ‘r’ of V, Σᵣ⁻¹ is the inverse of reduced ‘r’ rank matrix Σ, [symbol] is ‘r’ rank eigen vectors of matrix A, Λ_{A} is eigen values of matrix A, and Ψ_{A} is full rank eigen vectors of matrix A.
